(19) United States
(12) Patent Application Publication
(10) Pub. No.: US 2007/0079849 A1
(43) Pub. Date: Apr. 12, 2007

(54) Integrated chamber cleaning system

(76) Inventors: Richard Hogle, Oceanside, CA (US); Graham McFarlane, Murrieta, CA (US)

Correspondence Address: THE BOC GROUP, INC., 575 MOUNTAIN AVENUE, MURRAY HILL, NJ, 07974-2064, US

(21) Appl. No.: 11/248,059

(22) Filed: Oct. 12, 2005

(51) Int. Cl. B08B 7/04; B08B 9/00; H01L 21/306; C23C 16/00

(52) U.S. Cl. 134/10; 134/22.1; 156/345.29; 118/715

(57) ABSTRACT

Methods and apparatus for cleaning a process chamber using a fluorine gas, wherein the fluorine gas is at least partially recycled for further use in the cleaning cycle. The method includes generation of the fluorine, separation of fluorine from the waste gas of the process chamber and abatement of the waste. The apparatus includes a vacuum pump for moving the waste gas and fluorine gas to and from the process chamber and can further include a sensing unit to determine the cleaning cycle endpoint.

### FIELD OF THE INVENTION

The present invention relates generally to the field of chamber cleaning methods using fluorine-containing species. More specifically, the present invention relates to the use of F₂ gas as a process gas in chamber cleaning.

### BACKGROUND OF THE INVENTION

Semiconductor chip manufacturers have long recognized the deleterious effects of deposits, such as, for example, oxide deposits on the reaction chamber walls from the various chemical reactions and deposition processes that take place during chip manufacture. As impurities build up on reaction chamber inner surfaces, such as interior chamber walls, the risk increases that such impurities may be co-deposited on target work pieces, such as computer chips. Therefore, such chambers must be periodically cleaned during down cycles in the chip manufacturing process.

One known method for cleaning unwanted deposits from interior reaction chamber surfaces is to produce a fluorine plasma in the reaction chamber, under sub-atmospheric chamber walls. While diatomic fluorine (F₂) is an excellent candidate as a source for the fluorine plasma, other gases, such as, for example, NF₃, CF₄, C₂F₆, SF₆, etc. have been used as the fluorine radical source. In essence, any fluorine-containing gas that can be decomposed into active fluorine species potentially can be used for chamber cleaning. NF₃ has been a popular choice.

The dramatic surge in demand for NF₃ has resulted in a virtual global shortage of this relatively expensive material. In addition, most of the cleaning processes using NF₃ only consume about 15% of the fluorine contained within the NF₃ in the actual cleaning operation, with the remaining fluorine being exhausted, treated, neutralized and eventually discarded.

Cyclical adsorption processes are generally employed for use in fluorine recycling processes. Such preferred processes include pressure swing adsorption (PSA) and temperature swing adsorption (TSA) cycles, or combinations thereof. The adsorption can be carried out in an arrangement of two or more adsorption beds arranged in parallel and operated out of phase so that at least one bed is undergoing adsorption while another bed is being regenerated. However, single bed applications are known and widely used. Specific fluorine recycle applications into which the invention can be incorporated included vapor deposition and etching chamber cleaning processes, etc.

The fluorine-containing source compound, any other reagents, and inert gases used in the chamber cleaning process are typically supplied as compressed gases and are admitted into the chamber using a combination of pressure controllers and mass flow controllers to effect the cleaning process. The cleaning process itself requires that a plasma be maintained upstream of, or in the chamber, to break up the fluorine-containing source compound so that active fluorine ions and radicals are present to perform the cleaning chemistry. To maintain the plasma, the chamber is kept at a low pressure, typically between about 0.1 to 20 Torr absolute, by using a vacuum pump to remove the gaseous waste products and any unreacted feed gases that comprise the exhaust gas. The pressure in the chamber is typically controlled by regulating the flow of exhaust gas from the chamber to the chamber pump using a vacuum throttle valve and feedback controller to maintain the chamber pressure at the desired set point. The chamber cleaning operation is performed intermittently between deposition operations. Typically, one to five deposition operations are performed for every chamber cleaning cycle.

Unused radicals recombine to form fluorine, regardless of the fluorine source used. Such unused radicals are currently directed from the system as waste that must be treated and exhausted, such as to a facility abatement system. Therefore, an integrated fluorine source that improves the safe delivery of economical fluorine species to a chamber for cleaning cycles while recovering unused fluorine in the effluent, and reduces the demand of an abatement system while significantly conserving space would be advantageous.

### SUMMARY OF THE INVENTION

The present invention is directed to a combined F₂ feed, recycle and abatement system for chamber cleaning to optimize F₂ usage and abatement while simultaneously managing overall system size and F₂ storage and delivery constraints.

The present invention is further directed to a system that combines a safe, sub-atmospheric F₂ gas supply during the cleaning cycle, a recycle of the effluent gas through an absorber to absorb impurities (e.g. SiF₄), a recycle of the F₂ gas back to the cleaning process, and abatement of the gases once the cleaning cycle is complete. The present invention further contemplates the incorporation of an integrated gas analysis module to integrally determine the end point of the cleaning cycle.

The present invention is further directed to a method for cleaning a process chamber comprising a cleaning cycle utilizing fluorine gas from a fluorine source, a waste gas purification cycle, and an abatement system. An integral fluorine generator for producing a fluorine gas is provided with the generated fluorine gas directed to the process chamber. The contents of the process chamber are reacted with the fluorine gas and directed from the chamber as a fluorine waste stream under sub-atmospheric pressure to an adsorber for removing contaminants from the fluorine waste stream. The fluorine waste stream is converted into a recycled fluorine stream by directing recycled fluorine to an adsorber for impurity removal, and then directing the impurity-free recycled fluorine, on demand, to the process chamber or to a fluorine storage facility. An integral gas sensor can also be provided to the process to determine the presence of contaminants in the fluorine waste stream leaving the process chamber. The gas sensor uses the level of the contaminants generated in the cleaning cycle to control the chamber cleaning cycle.

According to a further embodiment, one method of the present invention is directed to incorporating an adsorber regenerating cycle to remove the collected impurities from the adsorber and direct the impurities to an abatement facility that is preferably integrated into the system.

The present invention is further directed to an apparatus for cleaning impurities from a process chamber comprising a process chamber having at least one inlet and at least one waste stream outlet, with the inlet in communication with a fluorine source. The apparatus further comprises a pump in fluid communication with the process chamber, a fluorine generator in communication with the process chamber or the pump as well as an integrated fluorine storage facility. The apparatus further comprises a purification chamber having an inlet and an outlet in communication with the process chamber and an abatement system for purifying a waste stream from the process chamber. An integrated gas sensor may also be provided to monitor the waste stream and determines the presence of contaminants in the fluorine waste stream leaving the process chamber. The sensor provides a signal to control the chamber cleaning cycle including directing the fluorine flow from the fluorine storage facility and fluorine generator.

### BRIEF DESCRIPTION OF THE DRAWINGS

FIG. 1 is a schematic representation of the apparatus according to one embodiment of the present invention.

### DETAILED DESCRIPTION

Recently, it has been discovered that fluorine (F₂) generation can be incorporated into many manufacturing processes to supply needed F₂ during the cleaning cycle. The presence of F₂ generators incorporated within manufacturing systems provides the supply of F₂ required for cleaning cycles in substantially real-time, greatly reducing the safety concerns as well as the cost of the system source gases. For large cleaning applications, waste F₂ can be excessive for a standard abatement system to handle. Therefore, the present invention facilitates reducing the total amount of F₂ using a recycle technique, such that the abatement system, and in turn, the entire F₂ delivery system can be appropriately reduced in size and cost.

With further regard to system safety improvement, according to the system of the present invention, fluorine is temporarily stored and transported to the processing chamber in a sub-atmospheric state. Therefore, even if a leak were to occur, air would leak inward rather than fluorine leaking out. According to the present invention, the system would be able to maintain a reservoir of sufficient fluorine without creating any accompanying hazard. Such advances further positively impact the space requirements of the system as the manifold through the lab that would route fluorine also would run at sub-atmospheric conditions and would not require a double containment configuration, thus simplifying the equipment constrains.

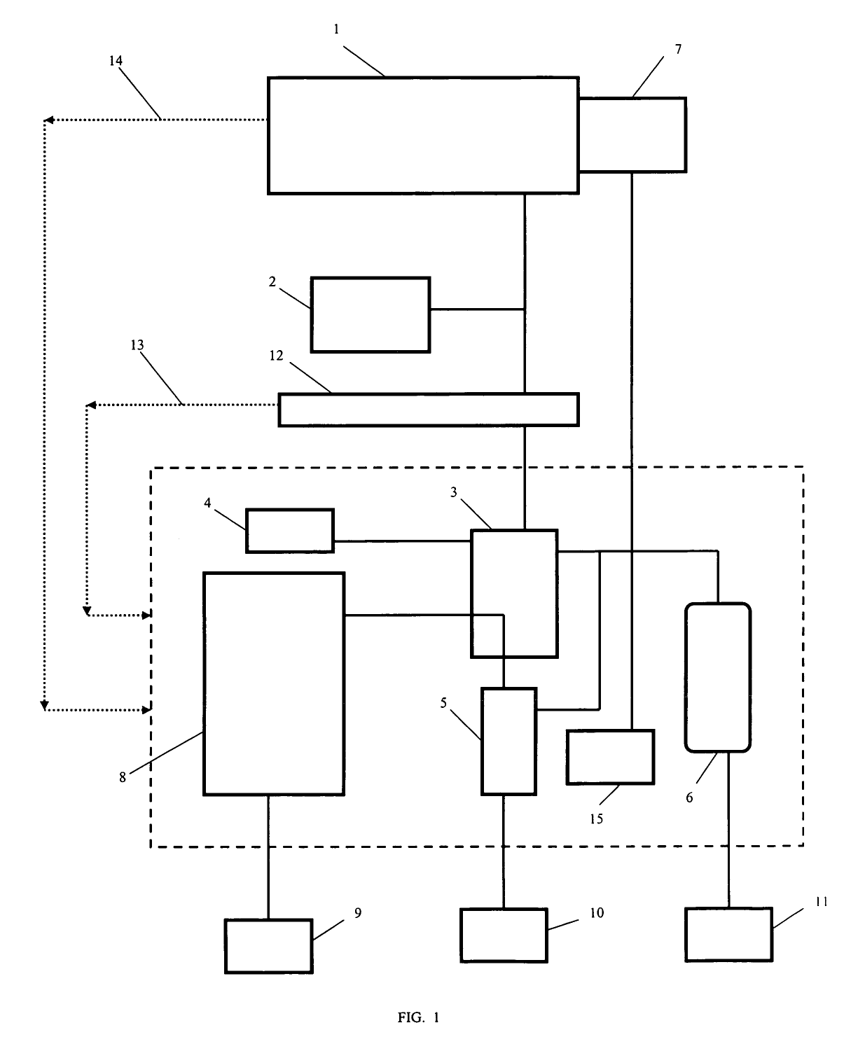

FIG. 1 shows a schematic diagram for one embodiment of the present invention. By-products and other impurities are produced in process chamber 1 during the process cycle. Exhaust gases are directed from the process chamber 1 to a process pump 2. During the cleaning cycle the exhaust gases are diverted through a cleaning pump 3. A purge gas source 4 provides a purge gas, such as argon, continuously into the cleaning pump 3 to provide ballast gas and to act as a purge for the dynamic seal needed in the cleaning pump 3 to prevent F₂ from seeping into the gear and motor housing. During the cleaning cycle, the process gas passes from the chamber 1 through an absorber 5 that absorbs the material cleaned from the chamber l, such as SiF₄. The gas is predominantly F₂ with the added purge gas from the purge gas source 4, coupled with contaminants from the chamber 1. After removing impurities by passing the gas through the absorber 5, the recycled gas is directed back to the Remote Plasma System (RPS) 7.

In addition to the exhaust gas coming from the process chamber, a predetermined amount of fluorine produced within the system from a central production system 11 is safely stored in a process accumulator 6. This fluorine can be introduced on demand with the exhaust gas from the process chamber 1 into cleaning pump 3 and added to the flow passing through RPS 7. As the process recycles, gases accumulate in the closed “loop” of the system and can be stored in a recycled F₂ vessel 15. During this recycle, the pressure in this loop will increase as more purge gas argon and F₂ are added. At a predetermined point, exhaust gases will be diverted to an abatement system 8 that will direct the fluorine and other gases in the exhaust and convert them to another form for effective disposal. The exhaust gas waste 9 treated to be of the quality required for emission into the atmosphere, such as through a house scrubbing system.

At the end of the cleaning cycle, the absorber 5 may be regenerated for the next cleaning cycle by flowing a regeneration gas, such as nitrogen, argon or mixtures thereof, from an inert gas source 10, through the absorber 5. The flow of regeneration gas is fed in reverse flow through the absorber 5 and desorbs the trapped contaminants, such as SiF₄. The flow of regeneration gas and contaminants is sent to the abatement system 8 for further processing and disposal. In addition, during the cleaning process, a flow of purge gas, such as nitrogen, argon or helium, from the inert gas source 10 may be allowed to flow into the absorber 5 and then to the RPS 7 in order to purge the chamber 1 and process pump 2.

To provide added control to this process, additional components can be added such as a cleaning gas analyzer 12 that analyzes the process gas either by Fourier Transform Infra-red (FTIR), atomic emission, mass spectroscopy, or other spectrographic methods. Once there is no SiF₄, or other contaminant in this process gas, a signal 13 is sent to the process signaling that the cleaning cycle of the system has been completed. Another control signal 14 is sent from the process chamber that will signal the cleaning system to commence the next chamber cleaning cycle. According to one embodiment of the present invention, this signaling feature is the only control connection between the process chamber and the cleaning tool.

The process pump is preferably a large displacement vacuum pump that is compatible with the use of purified fluorine. The available displacement is designed to deliver the required vacuum levels in the process chamber during the cleaning cycle.

The preferred fluorine-compatible cleaning pump is different than those generally used in the semiconductor industry. In particular, most semiconductor processing pumps are made of cast iron, to provide thermal stability, noise attenuation, strength and materials capability. In addition, stainless steel diaphragm pumps are often used, but have a relatively high level of inherent vibration and a need to detect leakage through the diaphragm. In the present application, the high flow rates preclude the use of a stainless steel diaphragm pump. In general, aluminum pumps are thought to be inferior in thermal stability, noise attenuation, strength and materials capability, but are still used in applications where low weight is important and the commensurate problems can be discounted. Typically, such applications involve only pumping air or inert gases. However, in the present invention, involving high levels of fluorine in the gas stream, aluminum has several advantages. For example, aluminum is less reactive to fluorine than cast iron. In fact, aluminum advantageously reacts slowly with fluorine to form a desirable aluminum fluoride passivation layer that minimizes or prevents further reaction with the fluorine.

Therefore, the present invention preferably uses a cleaning pump that is made of aluminum impregnated with a polytetrafluoroethylene (PTFE). The PTFE forms a relatively low friction surface to resist galling and to provide a protective layer to the aluminum that minimizes the need to passivate the pump surfaces with fluorine.

For fluorine applications, the use of a single shaft pump is advantageous. A single shaft pump produces no gear-related noise and provides a low level of well-controlled vibration, making it suitable for on-tool mounting. The design of the pump eliminates the need for any direct contact rotary shaft seals or flexing diaphragms to seal the fluorine in the pump. Rather, all seals that function to contain fluorine are static and hence reliable and predictable.

In addition, for fluorine application, the use of a pump with no bearings in the vacuum system is advantageous. The absence of bearings in the vacuum system means that there is no potential contact between lubricants avoiding any adverse reaction of the pump lubricant with the fluorine and also avoiding possible contamination of the process chamber or recycled fluorine gas from the pump lubricant. This in turn means that no maintenance is required to repair or replace contaminated pump parts.

According to the present invention, the preferred cleaning pump is a vacuum pump having pumping speeds of from about 20 m³/h to about 100 m³/h and capable of achieving pressures of from about 0.01 mbar to about 1000 mbar. Known dry vacuum pump technologies use an inert gas delta P and close tolerances to limit gas flow to the drive casing. These designs rely on close geometric clearances to control the pressure drop across annular clearances around the shaft, and combined with a pressure regulation device, prevent fluorine from entering the pump drive casing with a minimum flow rate of inert gas.

A pressure transducer may be used to sense pressure (vacuum) on the inlet side of cleaning pump and mass flow controllers supply the inert gas used to purge portions of the cleaning pump. A further pressure transducer senses pressure (vacuum) on the outlet side of the cleaning pump and a check valve controls the venting of the cleaning pump exhaust to the abatement system, which preferably operates at about 1 atmosphere absolute. The check valve further prevents backflow from the abatement system when the pressure transducer senses a pressure value less than the abatement system pressure. The check valve can be a mechanical backpressure regulator or a throttle valve together with a feedback controller operating with the pressure transducer to maintain a pressure set point.

Mass flow controllers also control the feed of source fluorine from the fluorine generator to the process chamber during the cleaning cycle. Depending on the desired process start up requirements, inert gas may or may not be required. Generally, the flow rate of the fluorine source gas from the fluorine generator will be reduced as recycled fluorine is returned from the adsorber to the process chamber.

In accordance with one embodiment of the present invention, the operation of the apparatus of FIG. 1 can be described as follows. When the process chamber 1 requires cleaning, a “start clean” signal 14 is sent and the cleaning cycle begins. The process pump 2 is closed off and the cleaning pump 3 is initiated. The purge gas (for purposes of this description; argon) from purge gas source 4 is supplied and passes through the cleaning pump 3 and is used to ignite the RPS 7. Once the RPS 7 is started, fluorine from the process accumulator 6 that has been collecting F₂ from the central F₂ production system 11, is introduced into the cleaning pump 3, adding fluorine to the RPS mix. At this point, all process gases are going through the absorber 5 and will be recycled through the RPS 7.

In the RPS, the F₂ is dissociated into energetic fluorine radicals and then a gas mixture containing amounts of fluorine radicals, nitrogen, argon, etc. is provided to the process chamber 1. In the process chamber 1, the fluorine radicals react with unwanted deposition products, such as silicon-containing oxides, etc. thereby cleaning the chamber of unwanted deposits. This reaction proceeds for a time period of from about one to several minutes until the unwanted deposition products are removed from the chamber. In typical cleaning operations only a small portion of the fluorine going to the process chamber 1 will remain in radical form and perform the cleaning. Fifty to eighty percent of the fluorine remains or recombines as F₂ and exits the process chamber 1 as F₂. Also exiting the process chamber 1, is SiF₄ that is formed as a cleaning process by-product. The SiF₄ is removed by the absorber 5, and the fluorine is fed back to the RPS 7. Once recycled fluorine is sent back to the RPS 7, the F₂ supplied from the process accumulator 6 may be decreased and the pressure in the F₂ storage vessel 15 increases.

During the cleaning cycle, the amount of gas eventually exceeds the capacity of the recycle loop and F₂ storage vessel 15, and some of the material is diverted into the abatement system 8 producing a stream that is directed to exhaust waste gas 9. The system also continues to recycle F₂ during this stage and absorb SiF₄ in the absorber 5. Because at least some of the fluorine is recycled, the total amount of fluorine sent to the abatement process can be reduced. In addition, much of the F₂ is held in the F₂ storage vessel 15 and can be abated slowly while the chamber 1 is running in wafer process mode. As a result, the operating cost and capital cost of the abatement system can be reduced, since the amount of abated gas is reduced by recycling some of the F₂ and since the abatement can be can carried out over a much greater time period requiring a significantly smaller abatement system than a conventional single pass approach. Moreover, the total amount of F₂ used in the cleaning cycle is significantly reduced also lowering the overall cost of operation.

In an optional embodiment, when the gas analyzer 12 senses an absence of SiF₄, a signal 13 is sent to the cleaning system to stop all fluorine flow through both the absorber 5 and the process accumulator 6. Alternatively, the clean cycle can simply be run for a predetermined time without the use of gas analyzer 12. The process chamber starts to pump down through the cleaning pump 3 to prepare for the next wafer processing cycles. It is also possible to introduce hydrogen from a hydrogen source feed (not shown) into the RPS 7 in order to convert residual fluorine in the chamber 1 so that it will not affect subsequent wafer processes.

When the wafer processing is proceeding the exhaust is diverted to process pump 2 and cleaning system regenerates. Regeneration gas, such as nitrogen, argon or mixtures thereof, from inert gas source 10, is fed to the absorber 5 in a reverse flow, and this regenerated gas passes into the feed of the cleaning pump 3. This reduces the pressure of the absorber 5 to less than 5 Torr, which desorbs the contaminants, such as, SiF₄. This is essentially a pressure swing absorption (PSA), process, during which all of the gases proceed to the abatement system 8, and all residual fluorine and SiF₄ are treated and disposed. Argon continues to be fed from purge gas source 4 continuously into the cleaning pump 3 to maintain the bearing purge and to provide diluent gas for the desorption process.

When a new cleaning process is required by the process chamber 1, a new signal 14 is sent and the cleaning cycle as described above begins anew.

The present invention provides a number of advantages. The recycle portion of the system reduces the total amount of fluorine needed for the cleaning cycle and also lessens the load on the abatement system. Because a vacuum pump drives the system, the process accumulator can safely store fluorine below atmospheric pressure and fluorine can be fed from the accumulator in a controlled manner corresponding with the amount of fluorine recycled from the process chamber. The reduction fluorine use and abatement system load allows a larger number of systems to be supplied from a single on-site F₂ generator than would be possible using conventional single pass processes.

One embodiment of various parameters for the operation discussed above and in accordance with the present invention follows. Initially, the purge gas flow rate is from about 1 slm (standard liters per minute) to about 6 slm. Pressure in the process chamber is kept between from about 0.1 Torr to about 20 Torr by a feedback loop established between a pressure reading instrument and a large throat vacuum valve and the cleaning pump. The flow of F₂ to the RPS is established from about 1 slm to about 20 slm. The argon flow may then be adjusted to meet process requirements but will normally be in the range of from about zero to about two times the F₂ flow rate. Once the flow rates have stabilized, pressure in the process chamber is maintained in the range of from about 0.1 Torr to about 20 Torr.

It is anticipated that other embodiments and variations of the present invention will become readily apparent to the skilled artisan in the light of the foregoing description and examples, and it is intended that such embodiments and variations likewise be included within the scope of the invention as set out in the appended claims.

We claim:

1. A method for cleaning a process chamber comprising the steps of:
creating fluorine gas from a fluorine generator;
directing an amount of the fluorine gas to a process chamber;
cleaning the process chamber thereby creating a fluorine waste stream;
directing the fluorine waste stream through a vacuum pump to an absorber for removing contaminants from the fluorine waste stream; and
separating a recycled fluorine stream from the fluorine waste stream.

2. The method of claim 1 further comprising the steps of:
sensing the presence of contaminants in the fluorine waste stream using a gas sensor; and
sending a signal from the gas sensor to end the cleaning process upon sensing a predetermined presence of contaminants.

3. The method of claim 1 further comprising the steps of:
regenerating the absorber with a regeneration gas.

4. The method of claim 1 further comprising the steps of:
storing the fluorine gas from the fluorine generator in a storage vessel below atmospheric pressure, until the fluorine gas is needed for the cleaning process.

5. The method of claim 1 further comprising the steps of:
storing the recycled fluorine from recycled fluorine stream in a recycle fluorine storage vessel; and
abating the fluorine waste steam and at least part of the recycled fluorine stream after the cleaning process is completed.

6. The method of claim 1 wherein the step of directing an amount of fluorine to the process chamber includes directing at least a portion of the recycled fluorine stream to the process chamber.

7. The method of claim 1 wherein the step of directing an amount of fluorine to the process chamber, comprises directing a pre-determined amount of fluorine from a fluorine source selected from the group consisting of the fluorine generator, the absorber, and combinations thereof.

8. The method of claim 4 wherein the step of directing an amount of fluorine to the process chamber, comprises directing a pre-determined amount of fluorine from a fluorine source selected from the group consisting of the fluorine generator, the absorber, the storage vessel and combinations thereof.

9. The method of claim 3 wherein the step of regenerating the absorber comprises:
directing the regeneration gas to the absorber;
removing impurities from the absorber using the regeneration gas; and
directing the regeneration gas and impurities form the absorber to an abatement system along with at least a portion of the recycled fluorine stream.

10. The method of claim 9 wherein the regeneration gas is argon, nitrogen or mixtures thereof.

11. The method of claim 1 wherein the fluorine waste steam includes silicon-containing impurities.

12. The method of claim 10 wherein silicon-containing impurities are SiF₄.

13. The method of claim 1 further comprising the steps of:
directing a purge gas to the vacuum pump.

14. The method of claim 13 wherein the purge gas is argon.

15. An apparatus for cleaning a process chamber comprising:
a process chamber having at least one inlet and at least one outlet;
a fluorine generator;
a fluorine storage vessel in fluid communication the fluorine generator and the inlet of the process chamber;
a fluorine recycle unit having an inlet and an outlet in communication with the process chamber;
an abatement system in communication with the outlet of the fluorine recycle unit; and
a vacuum pump communicating with the process chamber, the fluorine storage vessel, the fluorine recycle unit and the abatement system.

16. The apparatus of claim 15 further comprising:
a gas sensor in communication with the outlet of the process chamber.

17. The apparatus of claim 15 further comprising:
a first inert gas source in fluid communication with the vacuum pump.

18. The apparatus of claim 17 wherein the first inert gas source comprises an argon gas source.

19. The apparatus of claim 17 further comprising:
a second inert gas source in fluid communication with the fluorine recycle unit.

20. The apparatus of claim 19 wherein the second inert gas source comprises an argon gas source, a nitrogen gas source or both.

21. The apparatus of claim 14, wherein the inert gas source comprises nitrogen.

22. A method for cleaning a process chamber comprising the steps of:
continuously creating fluorine gas from a fluorine generator;
storing the fluorine gas in a fluorine storage vessel;
sending a signal from the process chamber to a system indicating that a cleaning cycle for the process chamber should begin, the system comprising the fluorine storage vessel, a fluorine recycle unit, an abatement unit and a vacuum pump;
directing an amount of the fluorine gas from the fluorine storage vessel to the process chamber;
cleaning the process chamber using the fluorine gas and creating a fluorine waste stream;
directing the fluorine waste stream through a vacuum pump to the fluorine recycle unit;
removing contaminants from the fluorine waste stream in the fluorine recycle unit to separate a recycled fluorine stream and from the fluorine waste stream;
storing at least a portion of the recycled fluorine stream in a recycled fluorine storage vessel;
directing a least a portion of the recycled fluorine from the recycled fluorine storage vessel to the process chamber;
directing a least a portion of the recycled fluorine from the recycled fluorine storage vessel to the abatement unit;
abating the recycled fluorine directed to the abatement unit;
sending a signal to the system indicating that the cleaning cycle for the process chamber should stop;
regenerating the fluorine recycle unit using a regeneration gas and creating a regeneration waste stream;
directing the regeneration waste stream and at least a portion of the recycled fluorine to the abatement unit; and
abating the regeneration waste stream and the recycled fluorine directed to the abatement unit.

23. The method of claim 22 wherein the step of sending a stop signal to the system comprises sending the stop signal from the process chamber to the system after a predetermined time period.

24. The method of claim 22 wherein the step of sending a stop signal to the system comprises sending the stop signal from a gas analysis unit to the system upon the gas analysis unit detection a predetermined level of contaminants in the fluorine waste stream.
